(19) United States
(12) Patent Application Publication
(10) Pub. No.: US 2022/0272298 A1
(43) Pub. Date: Aug. 25, 2022

(54) ANALOG COUNTER CIRCUITS AND READ-OUT INTEGRATED CIRCUITS AND INFRARED DETECTORS INCORPORATING THE SAME

(71) Applicant: L3 Cincinnati Electronics Corporation, Mason, OH (US)

(72) Inventors: Christopher Pope, Carrollton, TX (US); Joshua Lund, Dallas, TX (US)

(73) Assignee: L3 Cincinnati Electronics Corporation, Mason, OH (US)

(21) Appl. No.: 17/185,246

(22) Filed: Feb. 25, 2021

(51) Int. Cl. H04N 5/3745; H04N 5/378; G01J 1/46; G01R 19/165; H03K 17/687

(52) U.S. Cl. CPC H04N 5/37455; H04N 5/378; G01J 1/46; G01R 19/16538; H03K 17/687

(57) ABSTRACT

Analog counter circuits, read-out integrated circuits, and infrared detector devices are disclosed. In one embodiment, an analog counter circuit includes a first capacitor including a first terminal and a second terminal, a switch electrically coupled the first capacitor and a first voltage input, a field effect transistor, and a second capacitor. Setting the switch to an on-state pre-charges the first capacitor such that a voltage at the second terminal of the first capacitor is the first voltage. Applying a charge voltage at a charge input further charges the first capacitor. When a voltage at the second terminal of the first capacitor is greater than a threshold voltage of the field effect transistor, the field effect transistor turns on and transfers a charge on the first capacitor to the second capacitor.

### BACKGROUND

Image sensor devices, such as infrared sensors, include an array of pixels that absorb optical radiation in a predetermined wavelength band. Individual pixel sizes and pixels pitches have been reduced in recent years. To accommodate smaller pixel pitch size, mathematical operations such as counting may be performed within a pixel unit cell itself. Performing mathematical operations within the pixel further reduces information transfer. For example, an analog counter may be provided in the a pixel unit cell. The output of the analog counter is provided to a downstream component, such as an analog-to-digital converter, that interprets the count number. However, present analog counter circuits are not suitable for small pixel pitches, such as less than 12 μm. Present small-size analog counter circuits trade power consumption for linearity. In present small-size analog counter circuits, the output becomes non-linear as the count increases, which lowers the dynamic range of the counter.

Thus, alternative analog counter circuits for imaging applications are desired.

### SUMMARY

Embodiments of the present disclosure are directed to analog counter circuits, as well as read-out integrated circuits and infrared detectors incorporating analog counter circuits. The analog counter circuits disclosed herein may be incorporated directly into pixel unit cells of a read-out integrated circuit, for example. Embodiments provide for a linear counting output having at least a 7-bit dynamic range, and may be incorporated in a pixel array of a read-out integrated circuit having a pixel pitch of 12 μm or even lower.

In one embodiment, an analog counter circuit includes a first capacitor including a first terminal electrically coupled to a charge input, a switch electrically coupled to a second terminal of the first capacitor and a first voltage input, a field effect transistor, wherein a source terminal of the field effect transistor is electrically coupled to a second terminal of the first capacitor and a gate terminal is electrically coupled to a gate voltage input, and a second capacitor including a first terminal electrically coupled to ground and a second terminal electrically coupled to a drain terminal of the field effect transistor and a count output. The gate voltage input has a gate voltage that is higher than a first voltage at the first voltage input. Setting the switch to an on-state pre-charges the first capacitor such that a voltage at the second terminal of the first capacitor is the first voltage. Applying a charge voltage at the charge input further charges the first capacitor. When a voltage at the second terminal of the first capacitor is greater than a threshold voltage of the field effect transistor, the field effect transistor turns on and transfers a charge on the first capacitor to the second capacitor, thereby accumulating voltage on the second capacitor.

In another embodiment, a read-out integrated circuit includes an array of pixels, with each pixel including an analog counter circuit. The analog counter circuit includes a first capacitor including a first terminal electrically coupled to a charge input, a switch electrically coupled to a second terminal of the first capacitor and a first voltage input, a field effect transistor, wherein a source terminal of the field effect transistor is electrically coupled to a second terminal of the first capacitor and a gate terminal is electrically coupled to a gate voltage input, and a second capacitor including a first terminal electrically coupled to ground and a second terminal electrically coupled to a drain terminal of the field effect transistor and a count output. The gate voltage input has a gate voltage that is higher than a first voltage at the first voltage input. Setting the switch to an on-state pre-charges the first capacitor such that a voltage at the second terminal of the first capacitor is the first voltage. Applying a charge voltage at the charge input further charges the first capacitor. When a voltage at the second terminal of the first capacitor is greater than a threshold voltage of the field effect transistor, the field effect transistor turns on and transfers a charge on the first capacitor to the second capacitor, thereby accumulating voltage on the second capacitor.

In yet another embodiment, an infrared detector includes a focal plane array comprising an array of infrared detector devices, and a read-out integrated circuit including an array of pixels electrically coupled to the array of infrared detector devices. Each pixel includes an analog counter circuit. The analog counter circuit includes a first capacitor including a first terminal electrically coupled to a charge input, a switch electrically coupled to a second terminal of the first capacitor and a first voltage input, a field effect transistor, wherein a source terminal of the field effect transistor is electrically coupled to a second terminal of the first capacitor and a gate terminal is electrically coupled to a gate voltage input, and a second capacitor including a first terminal electrically coupled to ground and a second terminal electrically coupled to a drain terminal of the field effect transistor and a count output. The gate voltage input has a gate voltage that is higher than a first voltage at the first voltage input. Setting the switch to an on-state pre-charges the first capacitor such that a voltage at the second terminal of the first capacitor is the first voltage. Applying a charge voltage at the charge input further charges the first capacitor. When a voltage at the second terminal of the first capacitor is greater than a threshold voltage of the field effect transistor, the field effect transistor turns on and transfers a charge on the first capacitor to the second capacitor, thereby accumulating voltage on the second capacitor.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, wherein like structure is indicated with like reference numerals and in which:

FIG. 1 schematically illustrates an example analog counter circuit according to one or more embodiments described and illustrated herein;

FIG. 2 graphically illustrates input and output response of the example analog counter circuit of FIG. 1 according to one or more embodiments described and illustrated herein;

FIG. 3 schematically illustrates an infrared detector device incorporating analog counter circuits within pixels of a read-out integrated circuit according to one or more embodiments described and illustrated herein; and

FIG. 4 schematically illustrates a partial cross-sectional view of an example infrared detector device according to one or more embodiments described and illustrated herein.

### DETAILED DESCRIPTION

Embodiments of the present disclosure are directed to analog counter circuits, as well as read-out integrated circuits and infrared detectors incorporating analog counter circuits.

The analog counter circuits disclosed herein may be incorporated directly into pixel unit cells of a read-out integrated circuit, for example. The analog counter circuits provide for a linear counting output having at least a 7-bit dynamic range, and may be incorporated in a pixel array of a read-out integrated circuit having a pixel pitch of 12 μm or even lower. Further, the analog counter circuits described herein are power efficient, not requiring more power than that necessary to charge the small pre-charge capacitor and sufficiently raise its potential energy.

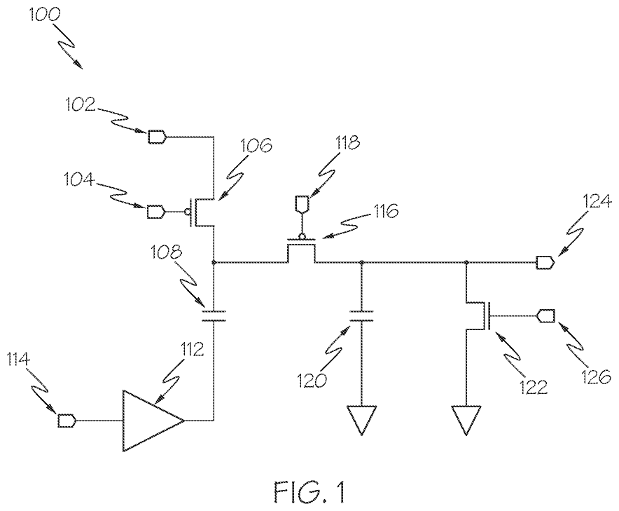

Referring now to FIG. 1, an example analog counter circuit 100 is schematically illustrated. The example analog counter circuit 100 generally comprises a first capacitor 108, a switch 106, field effect transistor 116, and a second capacitor 120. A first terminal of the first capacitor 108 is electrically coupled to a charge input 114, and a second terminal of the first capacitor 108 is electrically coupled to the switch 106 and to the source terminal of the field effect transistor 116.

In the illustrated embodiment, a buffer 112 electrically couples the charge input 114 to the first terminal of the first capacitor 108. However, it should be understood that in other embodiments no buffer is provided and the charge input 114 is directly coupled to the first terminal of the first capacitor 108. Due to its small size the first capacitor 108 may be a parasitic capacitor and constructed using spare metal, leaving silicon area for other signal processing devices.

In the illustrated embodiment, the switch 106 is configured as a field effect transistor, such as a metal-oxide-semiconductor field-effect transistor. However, embodiments are not limited thereto. The drain terminal of the switch 106 is electrically coupled to the second terminal of the first capacitor 108, while the source terminal of the switch 106 is electrically coupled to a voltage input 102. The gate terminal of the switch 106 is electrically coupled to a gate voltage input 104. A gate voltage on the gate voltage input 104 transitions the switch 106 between an on-state and an off-state. In the on-state, the voltage at the voltage input 102 is provided on the second terminal of the first capacitor 108. When the charge input 114 is connected to ground and held low, connection of the voltage input 102 to the second terminal pre-charges the first capacitor 108.

The field effect transistor 116 is configured to transfer substantially all of the charge of the first capacitor 108 to the second capacitor 120 so that charge is accumulated on the second capacitor 120 with each count. As a non-limiting embodiment, the field effect transistor 116 may be a positive metal-oxide-semiconductor field-effect transistor. The source terminal of the field effect transistor 116 is electrically coupled to the second terminal of the first capacitor 108 and the switch 106 (e.g., the drain terminal of the switch 106). The drain terminal of the field effect transistor 116 is electrically coupled to a second terminal of the second capacitor 120. The first terminal of the second capacitor 120 is electrically coupled to ground.

As stated above, during a count, charge from the first capacitor 108 is transferred to the second capacitor 120, which accumulates charge for each count. Thus, the analog counter circuit 100 performs addition by pumping a controlled amount of charge from the first capacitor 108 to the second capacitor 120, which acts as an accumulator capacitor, through the field effect transistor 116, which acts as a pass-through device.

In operation, first a pre-charge voltage is applied to the second terminal of the first capacitor 108 by setting the switch 106 to an on-state. The switch 106 of the illustrated embodiment is set to the on-state by applying a gate voltage PCH_N to the gate of the switch 106. The voltage VPCH at the voltage input 102 is provided on the second terminal of the first capacitor 108. Additionally, the first capacitor 108 is charged by setting the first terminal to ground.

At this point, the amount of charge in the system is:

Q₁=C₁V_{PCH}

Q₂=C₂V_{ACC}[N−1]

where:

Q₁ is the amount of charge on the first capacitor;

Q₂ is the amount of charge on the second capacitor; and

V_{ACC}[N−1] is the amount of voltage on the second capacitor before the accumulation event (i.e., before the present count).

Accumulation of charge on the second capacitor 120 occurs by turning off the switch 106 (i.e., disconnecting the second terminal of the first capacitor 108 from the voltage input 102) to allow the charge at the second terminal of the first capacitor 108 to float. Then, the charge input 114 is switched from ground to a charge voltage PCH, which may be the supply rail (e.g., 3.3V). The charge voltage PCH provided by the charge input 114 continues to charge the first capacitor 108, thereby increasing the voltage at the second terminal of the first capacitor 108 and the source terminal of the field effect transistor 116.

When the voltage at the source terminal of the field effect transistor 116 is greater than the threshold voltage Vt of the field effect transistor 116, the field effect transistor 116 turns on to allow the charge of the first capacitor 108 to transfer to the second capacitor 120. To make the output of the analog counter circuit 100 linear, it is desirable to completely transfer the charge from the first capacitor 108 to the second capacitor 120 rather than just sharing the charge. Setting the gate voltage VPG of the gate voltage input 118 on the gate terminal of the field effect transistor 116 to a sufficiently high voltage (e.g., the supply rail), causes the field effect transistor 116 to behave like a dynamic switch, in that it turns on when the potential is such that charge flows from the first capacitor 108 to the second capacitor 120 and turns off when charge flows the other direction in an attempt to redistribute or balance. Due to charge flowing in only one direction the new voltage on the second capacitor 120 becomes:

$${Q}_{120} [ n ] = {Q}_{120} [ n - 1 ] + {Q}_{108}$$

$${C}_{120} {V}_{120} [ n ] = {C}_{120} {V}_{120} [ n - 1 ] + {C}_{108} {V}_{PCH}$$

$${V}_{120} [ n ] = {V}_{120} [ n - 1 ] + \frac{{C}_{108}}{{C}_{120}} {V}_{PCH}$$

Thus, voltage level at the count output corresponds with the number of counts (i.e., the number of times the first capacitor 108 is pre-charged and then pumped to a voltage greater that the threshold voltage Vt of the field effect transistor 116).

When the charge on the first capacitor 108 transfers to the second capacitor 120, the voltage level at the source terminal of the field effect transistor 116 becomes lower than the threshold voltage Vt, and the field effect transistor 116 turns off. The first capacitor 108 may be then pre-charged again in preparation for the next count.

The output follows the linear function above until the voltage on the second capacitor 120 approaches a threshold voltage Vt of the field effect transistor gate voltage. At this point, the field effect transistor 116 does not turn off and allows charge to redistribute on both capacitors in an attempt to balance. This degrades linearity because the voltage step size is now dependent on the different between the voltage on 124 and the pre-charge voltage. This leads to the more familiar transfer function that is a weighted sum of the capacitors:

$${V}_{120} [ n ] = \frac{{C}_{120}}{{C}_{120} + {C}_{108}} {V}_{120} [ n - 1 ] + {V}_{PCH} \frac{{C}_{108}}{{C}_{120} + {C}_{108}}$$

$$Let α = \frac{{C}_{120}}{{C}_{120} + {C}_{108}}$$

$${V}_{120} [ n ] = ( 1 - α ) {V}_{PCH} + α {V}_{120} [ n - 1 ]$$

$${V}_{120} [ n ] = {V}_{120} [ n - 1 ] + {α}^{n} ( 1 - α ) {V}_{PCH}$$

Thus, in some embodiments, a reset switch 122 is provided between the count output 124 and ground. When the reset switch 122 is in the on state, the second terminal of the second capacitor 120 and the count output 124 is pulled to ground, thereby discharging the second capacitor 120. The second capacitor 120 may then once again begin accumulating charge as described above. In the illustrated embodiment, the reset switch 122 is a field effect transistor having a gate terminal that is electrically coupled to a reset input 126. When a voltage is provided at the reset input 126, the reset switch 122 turns on and discharges the second capacitor 120. The number of times that the reset switch is activated may be recorded to obtain an accurate count provided by the analog counter circuit 100.

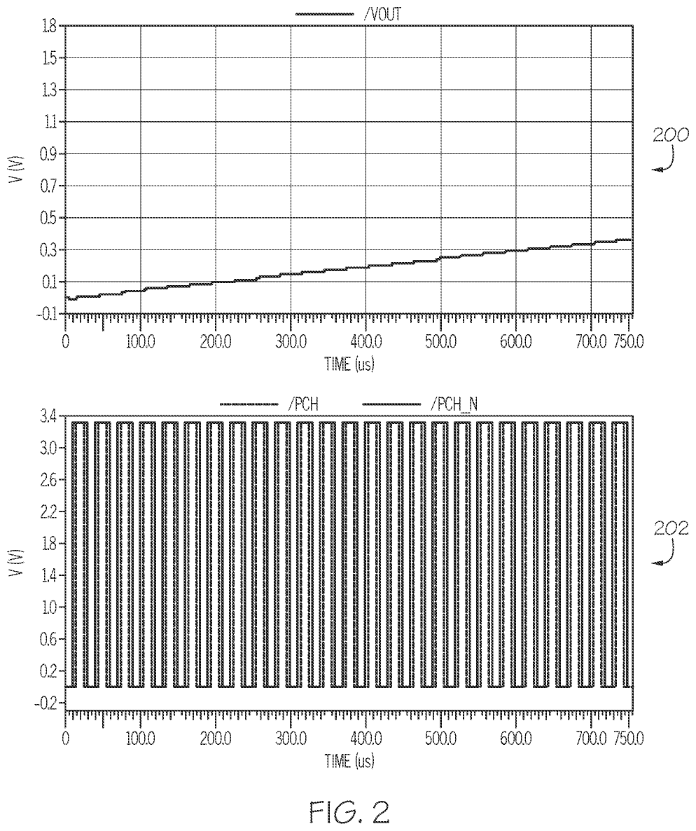

FIG. 2 includes two plots that illustrate the function and output of the analog counter circuit 100 illustrated by FIG. 1. Plot 202 illustrates the charge voltage PCH on the charge input 114 and the gate voltage PCH_N on the gate voltage input 104. As shown, the gate voltage PCH_N is set to high (e.g., the supply rail) while the gate voltage PCH_N is set to ground. This pre-charges the first capacitor 108. Next, the charge voltage PCH is set to high (e.g., the supply rail), which further charges the first capacitor 108 until its voltage exceeds the threshold voltage Vt of the field effect transistor 116.

Plot 200 illustrates the output response on the count output 124. As shown, each time the charge voltage PCH is set to high, the output response on the second capacitor 120 incrementally increases. The response is linear and provides for a high bit rate. As noted above, when the voltage on the second capacitor 120 causes the threshold voltage of the field effect transistor to increase close to the supply rail voltage provided at the gate terminal 118, the response becomes non-linear. At this stage, the reset input 126 is set to high to turn on the reset switch 122 and reset the second capacitor 120.

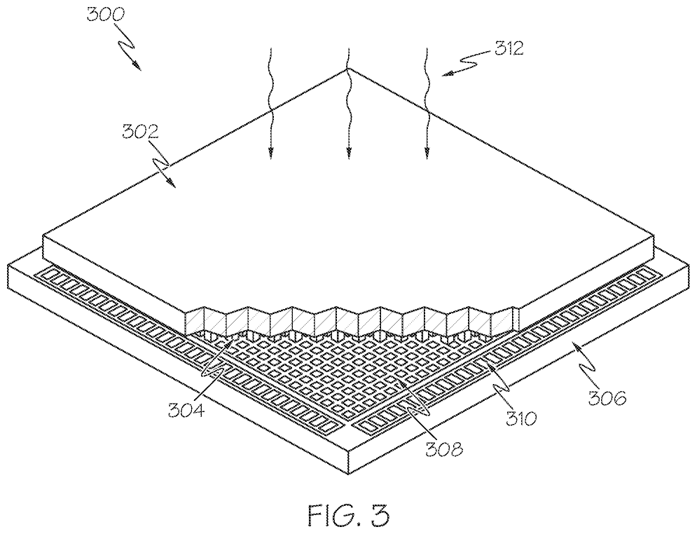

The small form-factor of the analog counter circuit may be used in a wide variety of applications. One such application is an infrared detector capable of detecting optical radiation in the near-infrared, infrared, and far-infrared spectral bands. Referring now to FIG. 3, a schematic illustration of an example infrared detector 300 is provided The infrared detector 300 comprises a focal plane array 302 having an array of detector devices capable of generating electrical current from incident photons 312. The focal plane array 302 may be electrically coupled to a read-out integrated circuit 306 by an array of bump bonds 304, such as, without limitation, indium bump bonds.

The example read-out integrated circuit 306 may be fabricated on a silicon substrate for example, and comprise an array of pixels 308 that are electrically connected to the bump bonds 304. Each pixel of the array of pixels 308 may include an individual analog counter circuit as described herein. Thus, the pixels have embedded counter devices capable of performing addition at the pixel level. In embodiments, the array of pixels 308 may have a pixel pitch of 12 μm or less. The read-out integrated circuit 306 further includes read-out terminals 310 around a perimeter for electrical connection to a connector to pass the electric signals from the read-out integrated circuit 306 to downstream devices, such as an analog to digital converter, for interpretation of the signals generated by the infrared detector.

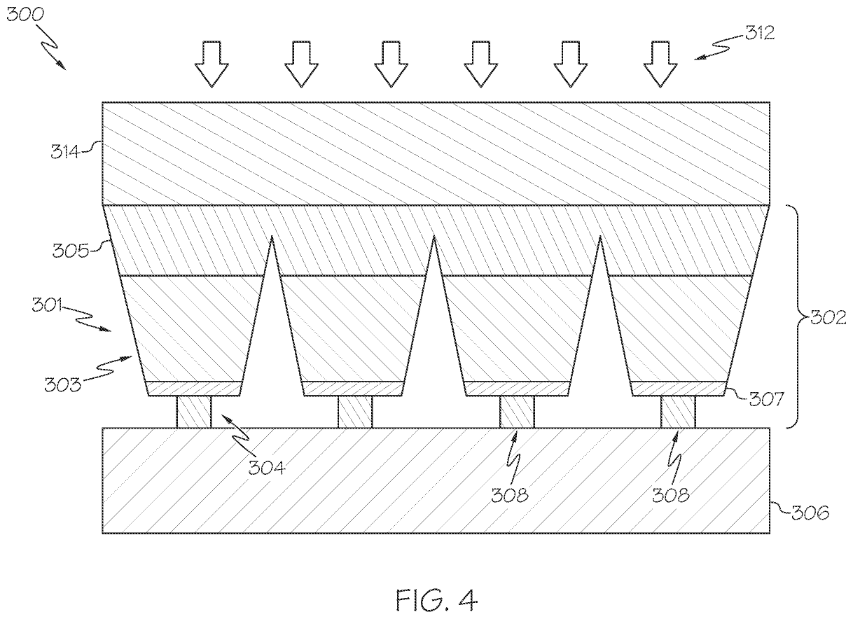

FIG. 4 illustrates a cross-sectional view of several infrared detector devices 301 of an example infrared detector 300. The example infrared detector 300 includes an optical window 314 fabricated from a material transmissive to optical radiation in a desired spectral band (e.g., infrared wavelength), a transparent ground plane 305, and an absorber layer 303 that is reticulated into the array of infrared devices 301. Each infrared detector device 301 has an electrically conductive contact layer 307 that is electrically coupled to an individual bump bond 304. The array of bump bonds 304 are electrically coupled to the array of pixels 308 that include the analog counter circuits described herein.

Photons 312 pass through the optical window 314 and the transparent ground plane 305 where they are then absorbed by the material of the absorber layer 303. The absorption of the photos causes generation of electrical signals that pass through the contact layers 307 and the bump bonds 304 and into the pixels 308 of the read-out integrated circuit 306.

Non-limiting examples of infrared detectors are disclosed in U.S. patent application Ser. No. 17/018,906 entitled “Mechanically Stacked Multicolor Focal Plane Arrays and Detection Devices,” the contents of which are incorporated by reference in its entirety.

It should now be understood that embodiments of the present disclosure are directed to analog counter circuits, as well as read-out integrated circuits and infrared detectors incorporating analog counter circuits. The analog counter circuits disclosed herein may be incorporated directly into pixel unit cells of a read-out integrated circuit, for example. The analog counter circuits provide for a linear counting output having at least a 7-bit dynamic range, and may be incorporated in a pixel array of a read-out integrated circuit having a pixel pitch of 12 μm or even lower.

The foregoing description of the various embodiments described herein has been presented for the purposes of illustration and description. It is not intended to be exhaustive or to limit the embodiments to the precise steps and/or forms disclosed. Many alternatives, modifications and variations will be apparent to those skilled in the art of the above teaching. Moreover, although multiple inventive aspects have been presented, such aspects need not be utilized in combination, and various combinations of inventive aspects are possible in light of the various embodiments provided above. Accordingly, the above description is intended to embrace all possible alternatives, modifications, combinations, and variations that have been discussed or suggested herein, as well as all others that fall with the principles, spirit and broad scope as defined by the claims.

1. An analog counter circuit comprising:
a first capacitor comprising a first terminal electrically coupled to a charge input;
a switch electrically coupled to a second terminal of the first capacitor and a first voltage input;
a field effect transistor, wherein a source terminal of the field effect transistor is electrically coupled to a second terminal of the first capacitor and a gate terminal is electrically coupled to a gate voltage input; and
a second capacitor comprising a first terminal electrically coupled to ground and a second terminal electrically coupled to a drain terminal of the field effect transistor and a count output, wherein:
the gate voltage input has a gate voltage that is higher than a first voltage at the first voltage input,
setting the switch to an on-state pre-charges the first capacitor such that a voltage at the second terminal of the first capacitor is the first voltage,
applying a charge voltage at the charge input further charges the first capacitor, and
when a voltage at the second terminal of the first capacitor is greater than a threshold voltage of the field effect transistor, the field effect transistor turns on and transfers a charge on the first capacitor to the second capacitor, thereby accumulating voltage on the second capacitor.

2. The analog counter circuit of claim 1, wherein the voltage at the count output corresponds to a number of times the switch is set to the on-state and the charge voltage is applied to the second terminal of the first capacitor.

3. The analog counter circuit of claim 1, wherein the field effect transistor comprises a positive metal-oxide-semiconductor field-effect transistor.

4. The analog counter circuit of claim 1, further comprising a buffer between the charge input and the first terminal of the first capacitor.

5. The analog counter circuit of claim 1, further comprising a reset switch electrically coupled to the count output and ground, wherein when the reset switch is in an on-state, the second capacitor is discharged to reset a count provided by a voltage on the second capacitor.

6. The analog counter circuit of claim 1, wherein the first capacitor is a parasitic capacitor.

7. The analog counter circuit of claim 1, wherein the switch is set to an off-state to cause the voltage at the second terminal of the first capacitor to float prior to applicant the charge voltage at the charge input.

8. The analog counter circuit of claim 1, wherein the analog counter circuit supports at least a 7-bit dynamic range.

9. The analog counter circuit of claim 1, wherein the analog counter circuit is sized such that it is capable of being incorporated within a pixel of a pixel array having a pixel pitch of greater than or equal to 12 μm.

10. A read-out integrated circuit comprising:
an array of pixels, each pixel comprising an analog counter circuit, wherein the analog counter circuit comprises:
a first capacitor comprising a first terminal electrically coupled to a charge input;
a switch electrically coupled to a second terminal of the first capacitor and a first voltage input;
a field effect transistor, wherein a source terminal of the field effect transistor is electrically coupled to a second terminal of the first capacitor and a gate terminal is electrically coupled to a gate voltage input; and
a second capacitor comprising a first terminal electrically coupled to ground and a second terminal electrically coupled to a drain terminal of the field effect transistor and a count output,
wherein:
the gate voltage input has a gate voltage that is higher than a first voltage at the first voltage input,
setting the switch to an on-state pre-charges the first capacitor such that a voltage at the second terminal of the first capacitor is the first voltage,
applying a charge voltage at the charge input further charges the first capacitor, and
when a voltage at the second terminal of the first capacitor is greater than a threshold voltage of the field effect transistor, the field effect transistor turns on and transfers a charge on the first capacitor to the second capacitor, thereby accumulating voltage on the second capacitor.

11. The read-out integrated circuit of claim 10, wherein the voltage at the count output corresponds to a number of times the switch is set to the on-state and the charge voltage is applied to the second terminal of the first capacitor.

12. The read-out integrated circuit of claim 10, wherein the field effect transistor comprises a positive metal-oxide-semiconductor field-effect transistor.

13. The read-out integrated circuit of claim 10, further comprising a buffer between the charge input and the first terminal of the first capacitor.

14. The read-out integrated circuit of claim 10, further comprising a reset switch electrically coupled to the count output and ground, wherein when the reset switch is in an on-state, the second capacitor is discharged to reset a count provided by a voltage on the second capacitor.

15. The read-out integrated circuit of claim 10, wherein the first capacitor is a parasitic capacitor.

16. The read-out integrated circuit of claim 10, wherein the switch is set to an off-state to cause the voltage at the second terminal of the first capacitor to float prior to applicant the charge voltage at the charge input.

17. The read-out integrated circuit of claim 10, wherein the analog counter circuit supports at least a 7-bit dynamic range.

18. The read-out integrated circuit of claim 10, wherein a pixel pitch of the array of pixels is greater than or equal to 12 μm.

19. An infrared detector comprising:
a focal plane array comprising an array of infrared detector devices;
a read-out integrated circuit comprising an array of pixels electrically coupled to the array of infrared detector devices, each pixel comprising an analog counter circuit, wherein the analog counter circuit comprises:
a first capacitor comprising a first terminal electrically coupled to a charge input;
a switch electrically coupled to a second terminal of the first capacitor and a first voltage input;
a field effect transistor, wherein a source terminal of the field effect transistor is electrically coupled to a second terminal of the first capacitor and a gate terminal is electrically coupled to a gate voltage input; and
a second capacitor comprising a first terminal electrically coupled to ground and a second terminal electrically coupled to a drain terminal of the field effect transistor and a count output,
wherein:
the gate voltage input has a gate voltage that is higher than a first voltage at the first voltage input,
setting the switch to an on-state pre-charges the first capacitor such that a voltage at the second terminal of the first capacitor is the first voltage,
applying a charge voltage at the charge input further charges the first capacitor, and
when a voltage at the second terminal of the first capacitor is greater than a threshold voltage of the field effect transistor, the field effect transistor turns on and transfers a charge on the first capacitor to the second capacitor, thereby accumulating voltage on the second capacitor.

20. The infrared detector of claim 19, wherein the analog counter circuit supports at least a 7-bit dynamic range, and a pixel pitch of the array of pixels is greater than or equal to 12 μm.
